(19) United States
(12) Patent Application Publication
(10) Pub. No.: US 2025/0273491 A1
(43) Pub. Date: Aug. 28, 2025

(54) DIE EJECTOR

(71) Applicant: FLC, Cheonan-si (KR)

(72) Inventors: Ganghyun MUN, Cheonan-si (KR); Sunghee CHO, Asan-si (KR)

(21) Appl. No.: 19/015,626

(22) Filed: Jan. 9, 2025

(30) Foreign Application Priority Data
Jan. 10, 2024 (KR) 10-2024-0004099

(51) Int. Cl. H01L 21/67; H01L 21/677

(52) U.S. Cl. CPC H01L 21/67132; H01L 21/67712

(57) ABSTRACT

The present disclosure relates to a die ejector, which separates a pickup-target chip from dicing tape, and more specifically, to a die ejector in which an ejector module and a vertical driving component are vertically integrated. The die ejector may include a plurality of ejecting blocks each including a contact portion provided on an upper end of the ejecting block and configured to come into contact with dicing tape, and a lifting plate provided on a lower end of the ejecting block, an ejector module including an ejector housing in which the ejecting blocks are installed, and a vertical driving unit including a plurality of vertical driving components configured to independently move the respective ejecting blocks upward or downward. The ejector module may be provided on an upper portion of the vertical driving unit, and the vertical driving unit may further include a seating portion on which the lifting plate of each of the ejecting blocks is seated.

### CROSS-REFERENCE TO RELATED APPLICATION

This application claims priority to Korean Patent Application No. 10-2024-0004099, filed on Jan. 10, 2024, which is incorporated herein by reference in its entirety.

### BACKGROUND

### Technical Field

The present disclosure relates to a die ejector, which separates a pickup-target chip from dicing tape, and more specifically, to a die ejector in which an ejector module and a vertical driving component are vertically integrated.

### Related Art

In a packaging process, which is a semiconductor back-end process, bonding refers to attaching a wafer chip to a substrate. One type of bonding, die bonding, involves attaching a semiconductor chip onto a lead frame or a printed circuit board (PCB) to establish an electrical connection of the semiconductor chip.

As shown in FIG. 1, in such die bonding, each semiconductor chip C that has undergone a dicing process exists in a state where the semiconductor chip C remains individually positioned and attached to dicing tape T. Typically, the semiconductor chip C is picked up using a plunger P and then placed onto a package substrate. Here, the semiconductor chip C, which is horizontally adhered to dicing tape T, is not easily separated due to adhesive. If excessive suction is applied, physical damage may occur to the semiconductor chip C. Therefore, a solution is needed to facilitate separation of the dicing tape T and the semiconductor chip C.

A structure that enables the separation of the semiconductor chip C is an ejector E. Generally, the ejector E applies pressure to a lower surface of the dicing tape T from beneath with an area smaller than that of the semiconductor chip C while simultaneously holding the dicing tape T by suction, thereby facilitating the separation of the dicing tape T from the semiconductor chip C, and assisting the pickup operation of the plunger P.

A conventional art related to such an ejector (hereinafter referred to as “conventional art”) is disclosed in Korean Patent No. 10-1931127. The conventional technology discloses a semiconductor manufacturing apparatus that includes a lift-up unit that pushes up a die from beneath dicing tape, and a collet that holds the die by suction. The lift-up unit includes a first unit having a plurality of rectangular blocks that contact the dicing tape, and a second unit having a plurality of concentric circular blocks each of which independently transmits up-and-down movement to a corresponding rectangular block. The semiconductor manufacturing apparatus allows the lift-up unit to be easily modified according to the type of products.

However, in the conventional art, the first unit and the second unit are separate from each other, requiring individual fabrication of the blocks in each unit, which increases the burden of fabrication costs and results in dimensional and shape tolerance deviations on assembly surfaces (contact surfaces) of the blocks.

### SUMMARY

The present disclosure has been devised to solve the above problem, and an object of the present disclosure is to provide a die ejector in which an ejector module is provided on an upper portion of a vertical driving unit and units related to driving ejecting blocks are integrated into a single structure, thereby reducing fabrication costs through component integration and minimizing occurrence of tolerance deviations.

A die ejector according to an embodiment of the present disclosure may include: a plurality of ejecting blocks each including a contact portion provided on an upper end of the ejecting block and configured to come into contact with dicing tape, and a lifting plate provided on a lower end of the ejecting block; an ejector module including an ejector housing in which the ejecting blocks are installed; and a vertical driving unit including a plurality of vertical driving components configured to independently move the respective ejecting blocks upward or downward. The ejector module may be provided on an upper portion of the vertical driving unit. The vertical driving unit may further include a seating portion on which the lifting plate of each of the ejecting blocks is seated.

Furthermore, each of the ejecting blocks may include a hollow space therein. The ejecting block having the contact portion that is provided at a relatively inner side may be installed in the hollow space.

The die ejector may further include an additional block housed in the ejector module, and installed in the hollow space of a central block that is disposed at an innermost side among the ejecting blocks. The additional block may include the lifting plate on a lower end thereof.

Each of the ejecting blocks may further include an upper body including a columnar portion, and a lower body provided under the upper body and having a set length in a vertical direction. The contact portion may be provided on an upper end of the columnar portion, and the lifting plate may be provided on a lower end of the lower body.

The columnar portion and the lower body may have different cross-sectional shapes.

The lifting plates of the respective ejecting blocks and the additional block may be disposed at an identical vertical position.

The lifting plates of the respective ejecting blocks and the additional block may come into contact with each other to form a single plate shape.

The lifting plates of the respective ejecting blocks and the additional block may each have a sectorial shape, and may come into contact with each other to form a disc shape.

The lifting plates of the respective ejecting blocks and the additional block may have an identical area in a plan view.

Each of the ejector blocks may further include a flange extending from the lower end of the lower body, with the lifting plate connected to a lower end of the flange.

### BRIEF DESCRIPTION OF THE DRAWINGS

FIG. 1 is a diagram illustrating the concept of an ejector.

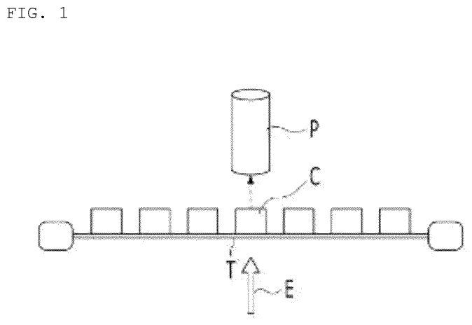

FIG. 2 is a perspective view illustrating an external shape of the ejector according to the present disclosure.

FIG. 3 is an internal cross-sectional view of the ejector according to the present disclosure.

FIG. 4 is a diagram separately illustrating an outer block among ejecting blocks.

FIG. 5 is a diagram separately illustrating an intermediate block among the ejecting blocks.

FIG. 6 is a diagram separately illustrating a central block among the ejecting blocks.

FIG. 7 is a diagram separately illustrating an additional block.

### DETAILED DESCRIPTION

While the present disclosure is susceptible to various modifications and alternative forms, embodiments (implantations) thereof will be described herein in detail. However, this is not intended to limit the present disclosure to particular modes of practice, and it should be understood that the present disclosure is to cover all modifications, equivalents, and alternatives falling within the spirit and scope of the present disclosure.

The terminology used herein is for the purpose of describing particular embodiments only and is not intended to be limiting the present disclosure. In the present disclosure, the singular forms are intended to include the plural forms as well, unless the context clearly indicates otherwise. It will be further understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof.

Unless otherwise defined, all terms including technical and scientific terms used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terms “first”, “second”, etc. are used only for the purpose for distinguishing a constitutive element from other constitutive elements, but the constitutive element should not be limited to a manufacturing order, and the terms described in the detailed description may not be consistent with those described in the claims.

The present disclosure relates to a die ejector (hereinafter referred to as the present apparatus) which separates a pickup-target chip from dicing tape, and may broadly include ejecting blocks 1 that come into contact with the dicing tape, an ejector module 3 that accommodates the ejecting blocks 1, and a vertical driving unit 5 that independently moves each of the ejecting blocks 1 upward and downward. The present apparatus has the purpose and effect of reducing fabrication costs and minimizing tolerance deviations due to element integration by providing the ejector module 3 above the vertical driving unit 5 and integrating units related to driving the ejecting blocks 1 The present apparatus will be into a single structure. described in detail with reference to the accompanying drawings.

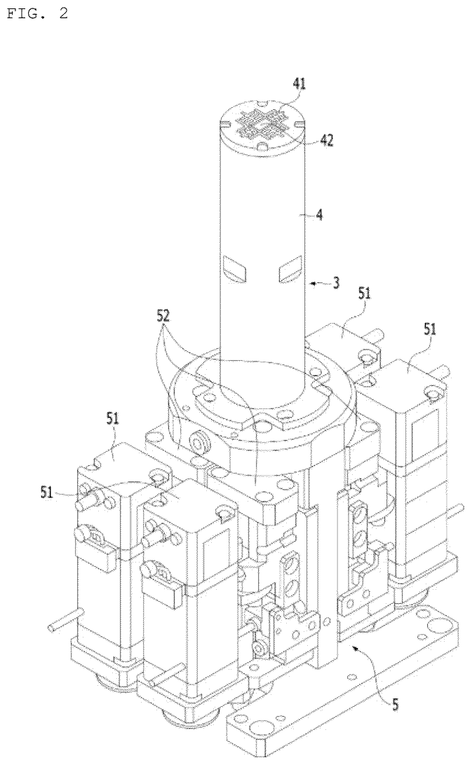

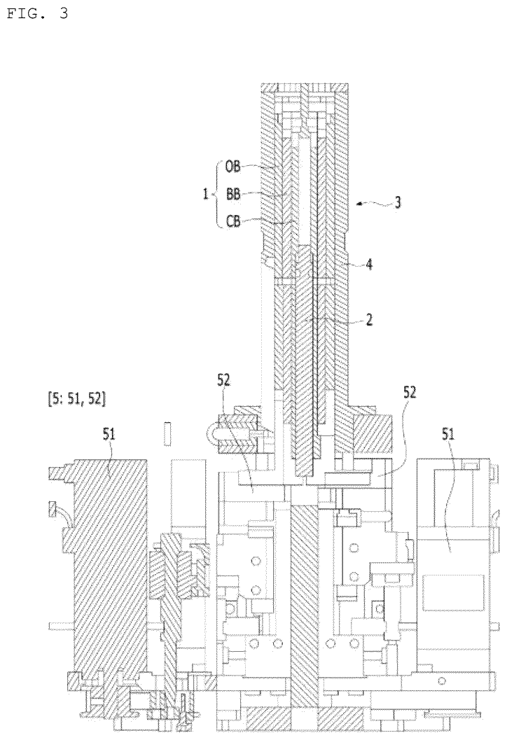

As shown in FIGS. 2 to 7 illustrating embodiments of the present disclosure, the present apparatus may include an ejecting block 1 that comes into contact with the dicing tape. The ejecting block 1 may be provided in plurality. Referring to FIG. 3, the ejecting blocks 1 may include a central block CB disposed at an innermost position based on a contact portion 14 of each of the ejecting blocks 1, an outer block OB disposed at an outermost position, and an intermediate block BB disposed between the central block CB and the outer block OB. For convenience of explanation, the description of the present disclosure assumes three ejecting blocks 1. However, it should be noted that the present disclosure does not exclude embodiments in which a plurality of intermediate blocks BB are provided so that four or more ejecting blocks 1 are provided.

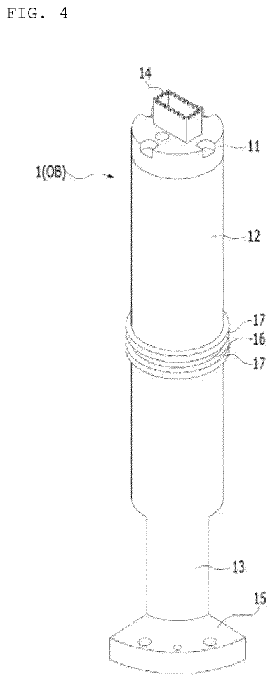

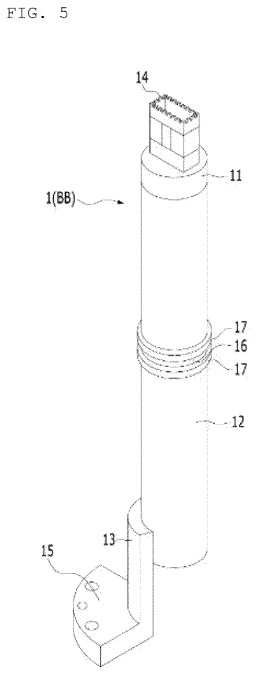

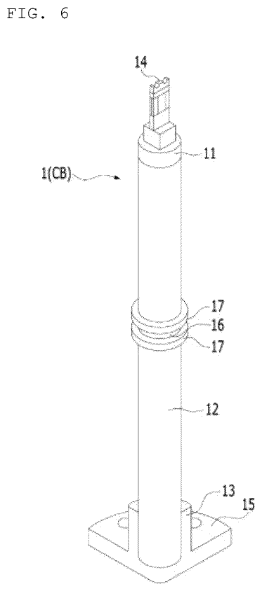

Specifically, referring to FIG. 4 illustrating the outer block OB, FIG. 5 illustrating the intermediate block BB, and FIG. 6 illustrating the central block CB, each of the ejecting blocks 1 may include an upper body 11 provided at an upper portion, a lower body 12 provided below the upper body 11, a flange 13 provided on a lower end of the lower body 12, a contact portion 14 provided on an upper surface of the upper body 11, a lifting plate 15 provided on a lower end of the flange 13, and an intermediate groove 16 and an intermediate protrusion 17 that are provided at an intermediate portion of the lower body 12.

Describing each part, as illustrated in FIGS. 3 to 6, the upper body 11 is an element corresponding to an upper portion of a main body of the ejecting block 1, while the lower body 12 is an element corresponding to a lower portion of the main body of the ejecting block 1. The upper body 11 and the lower body 12 may be integrally formed or may be configured as separate bodies coupled to each other by a predetermined unit. The upper body 11 and the lower body 12 may each have a polygonal or circular cross-section and may be configured in a columnar shape with a predetermined length in a vertical direction. In the accompanying drawings, it can be seen that each of the upper and lower bodies 11 and 12 is configured as a cylindrical structure with a circular cross-section.

The flange 13 is an element provided to align a vertical arrangement height of the lifting plate 15 of each of the ejecting blocks 1. As illustrated in FIGS. 4 to 6, the flange 13 extends from the lower end of the lower body 12. The flange 13 extends over only a portion of an entire circumference of the lower body 12, thus forming an arch shape, and a length thereof corresponds to an arc length of a central side of the lifting plate 15.

As shown in FIGS. 4 to 6, the flanges 13 of the respective ejecting blocks 1 are configured such that the flange 13 of the outer block OB is longest, while the flange 13 of the central block CB is shortest. The foregoing configuration is due to the fact that the outer block OB is positioned at the outermost side, whereas the central block CB is positioned at the innermost side.

The contact portion 14 is configured to come into contact with the dicing tape. As illustrated in FIGS. 4 to 6, the upper body 11 includes a columnar portion protruding upward, and the contact portion 14 is provided on an upper end of the columnar portion. More precisely, an upper surface of the columnar portion may serve as the contact portion 14. Particularly, the columnar portion and the lower body 12 may have different cross-sectional shapes. In FIGS. 4 to 6, an embodiment is illustrated in which the columnar portion has a rectangular cross-section, while the lower body 12 has a circular cross-section. Due to the aforementioned difference in cross-sectional shapes, during a process in which the columnar portion passes through an exposed portion 42 of an ejector hood, element removal may be effectively prevented by catching.

The lifting plate 15 is an element configured to contact a seating portion 52 of the vertical driving unit 5 so as to be seated on the vertical driving unit 5, and may be provided at the lower end. Precisely, the lifting plate 15 may be provided on the lower end of the lower body 12. More precisely, the lifting plate 15 may be provided in a form extending in a horizontal direction from the lower end of the flange 13. Particularly, the lifting plates 15 of the respective ejecting blocks 1 may be arranged at the same vertical position. The aforementioned configuration will be further described in detail below in conjunction with an additional block 2.

The intermediate groove 16 provided at the intermediate portion of the lower body 12 is a space where an O-ring or the like is fitted. The aforementioned sealing prevents vacuum leakage by blocking a gap between the lower bodies.

The intermediate protrusion 17 functions to prevent the O-ring from being axially displaced.

The present apparatus may further include the additional block 2, which is housed in the ejector module 3 and installed in a hollow space of the central block CB, which is disposed at the innermost side among the ejecting blocks 1.

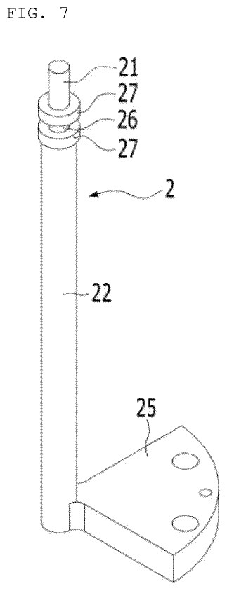

As shown in FIG. 7 illustrating the additional block 2, the additional block 2 may include an upper body 21, which corresponds to an upper portion of a main body thereof, a lower body 22, which corresponds to a lower portion of the main body, a lifting plate 25 provided on a lower end of the lower body 22, an intermediate groove 26, and an intermediate protrusion 27. Since the elements of the additional block 2 are similar to those of the ejecting blocks 1, redundant descriptions thereof will be omitted.

As an embodiment related to the ejecting block 1, as confirmed in FIG. 3, each of the ejecting blocks 1 includes the hollow space therein, and another ejecting block 1 that has the contact portion 14 provided at a relatively inner side may be installed in the hollow space. In other words, the ejecting blocks 1 are provided in an overlapping manner, in which the outer block OB accommodates the intermediate block BB, and the intermediate block BB accommodates the central block CB. The ejecting blocks 1 are configured in a shape in which the upper portions thereof overlap each other, allowing the contact portions 14 to be naturally arranged from the outer side to the inner side.

Furthermore, as can be confirmed in FIGS. 3 to 7, the lifting plates 15 and 25 of the respective ejecting blocks 1 and the additional block 2 may be arranged at the same vertical position. To this end, the flanges 13 and 23 are not provided over the entire circumference of the lower bodies 12 and 22, but only over a partial section. The lifting plates 15 and 25 of the respective ejecting blocks 1 and the additional block 2 may come into contact with each other to form a single plate shape. Through the aforementioned configuration, the vertical driving unit 5 may move upward or downward the lifting plates 15 and 25, which are arranged on the same horizontal plane, thereby enabling the upward or downward movement of the ejecting blocks 1.

Furthermore, in the present apparatus, the lifting plates 15 and 25 of the respective ejecting blocks 1 and the additional block 2 may each have a sectorial shape, and may come into contact with each other, thereby forming a disc shape. As confirmed in FIGS. 4 to 7, since the ejector module 3 is formed in an overall cylindrical shape, each of the lifting plates 15 and 25 is configured in a sectorial shape. Preferably, the lifting plates 15 and 25 of the respective ejecting blocks 1 and the additional block 2 may have the same area in a plan view. To ensure reliable upward or downward movement of all the ejecting blocks 1 by the vertical driving unit 5, it is desirable that the lifting plates 15 and 25 have the same area. If the areas differ, variations in friction or load during the upward or downward movement of the ejecting blocks 1 may occur, potentially causing obstruction or instability in upward or downward motion.

The present apparatus may further include the ejector module 3 that accommodates the ejecting blocks 1. The ejector module 3 may include an ejector housing 4 in which the ejecting blocks 1 are installed. The ejector housing 4, also referred to as an ejector hood, serves as an external structure that encloses and protects internal elements of the ejector module 3. The ejector module 3 may include, in an upper surface thereof, a suction port 41 provided to secure a lower surface of the dicing tape T by suction and an exposed portion 42 provided at the center to allow the ejecting blocks 1 to be exposed. In the attached drawings, an embodiment is illustrated in which the exposed portion 42 is configured in a rectangular shape, and the suction port 41 is configured as holes arranged uniformly around the exposed portion 42. However, the configuration is not necessarily limited to the aforementioned shape.

The present apparatus may further include the vertical driving unit 5, which includes a plurality of vertical driving components 51 configured to independently move the respective ejecting blocks 1 upward and downward. The vertical driving components 51 may each include, as a series of elements for moving the corresponding ejecting block 1 upward and downward, a lifting element coupled to the seating portion 52 and configured to move upward or downward, a lifting rod threadedly coupled with the lifting element, and a motor, pulley, and belt, which rotate the lifting rod, although not illustrated in the drawings.

Particularly, in the present apparatus, the ejector module 3 may be provided above the vertical driving unit 5, and the vertical driving unit 5 may further include the seating portion 52 on which the respective lifting plates 15 of the ejecting blocks 1 are seated. The seating portion 52 may be configured as a plate element, allowing the configuration for implementing the upward or downward movement of each of the ejecting blocks 1 to be integrated into the lower body 12, the lifting plate 15, and the like. Through the integration of components, the present disclosure may provide the effect of reducing fabrication costs and minimizing tolerance deviations.

In the present disclosure having the above-mentioned configuration and features, an ejector module is provided on an upper portion of a vertical driving unit and units related to driving ejecting blocks are integrated into a single structure, thereby reducing fabrication costs through component integration and minimizing occurrence of tolerance deviations.

The present disclosure described above with reference to the accompanying drawings may be variously modified and changed by those of ordinary skill in the art, and such modifications and changes that are not limited by the claims should be construed as being included in the scope of the present disclosure.

What is claimed is:

1. A die ejector comprising:
a plurality of ejecting blocks each including a contact portion provided on an upper end of the ejecting block and configured to come into contact with dicing tape, and a lifting plate provided on a lower end of the ejecting block;
an ejector module including an ejector housing in which the ejecting blocks are installed; and
a vertical driving unit including a plurality of vertical driving components configured to independently move the respective ejecting blocks upward or downward,
wherein the ejector module is provided on an upper portion of the vertical driving unit, and the vertical driving unit further includes a seating portion on which the lifting plate of each of the ejecting blocks is seated.

2. The die ejector of claim 1,
wherein each of the ejecting blocks includes a hollow space therein, and
wherein the ejecting block having the contact portion that is provided at a relatively inner side is installed in the hollow space.

3. The die ejector of claim 2, further comprising an additional block housed in the ejector module, and installed in the hollow space of a central block that is disposed at an innermost side among the ejecting blocks,
wherein the additional block includes the lifting plate on a lower end thereof.

4. The die ejector of claim 3,
wherein each of the ejecting blocks further includes an upper body including a columnar portion, and a lower body provided under the upper body and having a set length in a vertical direction, and
wherein the contact portion is provided on an upper end of the columnar portion, and the lifting plate is provided on a lower end of the lower body.

5. The die ejector of claim 4, wherein the columnar portion and the lower body have different cross-sectional shapes.

6. The die ejector of claim 4, wherein the lifting plates of the respective ejecting blocks and the additional block are disposed at an identical vertical position.

7. The die ejector of claim 6, wherein the lifting plates of the respective ejecting blocks and the additional block come into contact with each other to form a single plate shape.

8. The die ejector of claim 7, wherein the lifting plates of the respective ejecting blocks and the additional block each have a sectorial shape, and come into contact with each other to form a disc shape.

9. The die ejector of claim 8, wherein the lifting plates of the respective ejecting blocks and the additional block have an identical area in a plan view.

10. The die ejector of claim 6, wherein each of the ejector blocks further includes a flange extending from the lower end of the lower body, with the lifting plate connected to a lower end of the flange.
